(19) United States
(12) Patent Application Publication
(10) Pub. No.: US 2023/0397333 A1
(43) Pub. Date: Dec. 7, 2023

(54) ULTRA-LASER THOUGH HOLE (ULTH) BY MULTI-STACKED CORE CONCEPT

(71) Applicant: Intel Corporation, Santa Clara, CA (US)

(72) Inventors: Eng Huat GOH, Ayer Itam (MY); Chee Kheong YOON, Bayan Lepas (MY); Telesphor KAMGAING, Chandler, AZ (US); Jooi Wah WONG, Bukit Mertajam (MY); Min Suet LIM, Gelugor (MY); Kavitha NAGARAJAN, Bangalore (IN); Chan Kim LEE, Banyan Lepas (MY); Chu Aun LIM, Hillsboro, OR (US)

(21) Appl. No.: 17/833,568

(22) Filed: Jun. 6, 2022

(51) Int. Cl. H05K 1/11; H05K 3/42; H05K 3/46

(52) U.S. Cl. CPC H05K 1/115; H05K 3/429; H05K 3/4644; H05K 2201/09827; H05K 2201/0275; H05K 2203/107; H05K 2203/02; H05K 2201/09854

(57) ABSTRACT

Embodiments disclosed herein include package substrates. In an embodiment, the package substrate comprises a core. In an embodiment, the core comprises a first sub-core layer and a second sub-core layer. In an embodiment, a via is provided through the first sub-core layer and the second sub-core layer. In an embodiment, the via comprises a first hourglass shape in the first sub-core layer and a second hourglass shape in the second sub-core layer. In an embodiment, a front-side buildup layer is over the core and a backside buildup layer is under the core.

### TECHNICAL FIELD

Embodiments of the present disclosure relate to electronic packages, and more particularly to packaging architectures that include small laser through holes in a stacked core concept approach.

### BACKGROUND

A laser through hole (LTH) is the interconnect formed through the core layer in a typical package substrate in order to electrically couple a front-side buildup layer to a backside buildup layer. The LTHs are formed with a laser drilling process, and the size of the LTH is dependent on the thickness of the core. For example, a 200 μm thick core currently requires a pad size of 190 μm and a via diameter of 90 μm. This already large size increases to 100 μm via diameter and 220 μm pad size when the core thickness increases to 250 μm. The larger LTH size leads to a lot of design challenges, especially for small mobile packages.

As can be appreciated, decreasing the core thickness allows for more flexibility to provide thinner LTH features. Unfortunately, reducing the core thickness results in an increase in the warpage of the package substrate. With continuous growth in the die size (e.g., due to more core processing power, graphic performance, IO features, etc.), decreasing the core thickness is not a tenable solution.

### BRIEF DESCRIPTION OF THE DRAWINGS

FIG. 1A is a cross-sectional illustration of a monolithic core.

FIG. 1B is a schematic diagram of the routing capabilities available when using a monolithic core.

FIG. 2A is a cross-sectional illustration of a core that is comprised of two sub-core layers, in accordance with an embodiment.

FIG. 2B is a cross-sectional illustration of a core that is comprised of four sub-core layers, in accordance with an embodiment.

FIG. 2C is a schematic diagram of the routing capabilities that enable layer count reduction when using a plurality of sub-core layers, in accordance with an embodiment.

FIG. 3A is a cross-sectional illustration of a typical via that is formed using a micro via architecture in a coreless package substrate.

FIG. 3B is a cross-sectional illustration of a via with hourglass shaped cross-sections that is formed through a core that comprises a plurality of sub-core layers, in accordance with an embodiment.

FIG. 4A is a cross-sectional illustration of a sub-core layer, in accordance with an embodiment.

FIG. 4B is a cross-sectional illustration of a pair of sub-core layers that are adhered to each other, in accordance with an embodiment.

FIG. 4C is a cross-sectional illustration of the pair of sub-core layers after a first via opening is formed into both of the sub-core layers, in accordance with an embodiment.

FIG. 4D is a cross-sectional illustration of the sub-core layers being separated from each other, in accordance with an embodiment.

FIG. 4E is a cross-sectional illustrations of the sub-core layers after they have been flipped and brought back into contact with each other, in accordance with an embodiment.

FIG. 4F is a cross-sectional illustration of the sub-core layers after second via openings are formed through the sub-core layers to form a continuous opening through entire thicknesses of the first sub-core layer and the second sub-core layer, in accordance with an embodiment.

FIG. 4G is a cross-sectional illustration of the sub-core layers being separated from each other, in accordance with an embodiment.

FIG. 4H is a cross-sectional illustration of the sub-core layers being adhered to each other by an adhesive, in accordance with an embodiment.

FIG. 4I is a cross-sectional illustration of the sub-core layers after the adhesive is removed from the via openings, in accordance with an embodiment.

FIG. 4J is a cross-sectional illustration of the sub-core layers after vias and pads are formed, in accordance with an embodiment.

FIG. 4K is a cross-sectional illustration of the sub-core layers after a buildup layer is provided over the pads, in accordance with an embodiment.

FIG. 4L is a cross-sectional illustration of routing layers over the buildup layers, in accordance with an embodiment.

FIG. 4M is a cross-sectional illustration of the sub-core layers after additional buildup layers are formed, in accordance with an embodiment.

FIG. 5 is a cross-sectional illustration of an electronic system that comprises a package substrate with a core that is fabricated with a plurality of sub-core layers, in accordance with an embodiment.

FIG. 6 is a schematic of a computing device built in accordance with an embodiment.

### EMBODIMENTS OF THE PRESENT DISCLOSURE

Described herein are packaging architectures that include small laser through holes in a stacked core concept approach, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, laser through hole (LTH) drilling in the core is limited to larger via diameters. As such, embodiments disclosed herein include a stacked core architecture in order to provide the necessary LTH diameter without reducing the overall thickness of the core. In an embodiment, the core may have two or more stacked sub-cores, or four or more stacked sub-cores. For example, a set of four 50 μm sub-cores can be stacked to provide a 200 μm core, or a pair of 100 μm sub-cores can be stacked to provide a 200 μm core. The sub-cores can be adhered to each other by an adhesive or the like. Accordingly, laser drilling only needs to be capable of passing through much smaller thicknesses. This enables a reduction in the diameters and pad sizes of the LTH.

In some embodiments, the reduction in via diameters and pad sizes may allow for total layer count reduction. For example, the smaller sizes of the LTH allows for signals to pass through a thickness of the core. As such, a signaling layer that is traditionally on the front side of the package substrate can be moved to the backside of the package substrate on the opposite side of the core. This may enable layer count reduction, such as a reduction from a ten layer package to a six layer package.

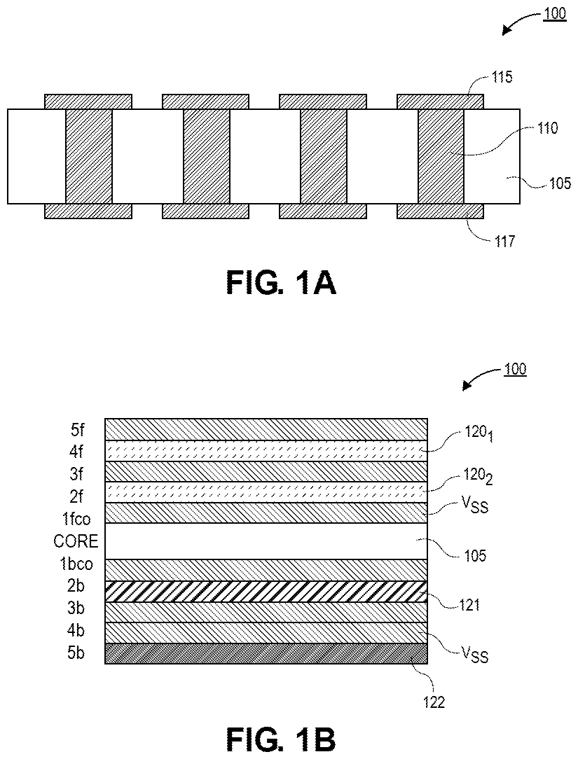

Referring now to FIG. 1A, a cross-sectional illustration of an existing package substrate 100 is shown. The package substrate 100 may comprise a core 105. Buildup layers (not shown) may be provided over and under the core 105. The core 105 may comprise a fiber reinforced (e.g., glass fiber) substrate. The vias 110 may be formed with a laser drilling process. The laser drilling process may have minimum feature sizes that are dictated by the thickness of the core 105. For example, in a 200 μm thick core, the vias 110 may have a diameter that is approximately 90 μm. Pads (e.g., pads 115 over the top surface and pads 117 over the bottom surface) may have diameters that are approximately 190 μm. The large dimensions and pitches of the vias 110 and the pads 115 and 117 prevent the passing of signals through the core 105. This is because the pitch of the bumps on the overlying die (not shown) are smaller than the pitch of the vias 110. Accordingly, all of the signal routing must be provided on the front-side buildup layers. This increases the layer count of the package substrate 100.

For example, a schematic of the routing is shown in FIG. 1B. In each layer of the package substrate 100, different types of routing are shown. For example in the front-side layers 1fco to 5f, signal routing 1201 and 1202 are provided. The signal traces are sandwiched between ground traces Vss. On the bottom surface of the core 105, ground traces Vss may be provided (e.g., in layers 1bco, 3b, and 4b). A BSR routing 121 may be provided on layer 2b, and solder balls 122 may be proved on layer 5b. Typically, the number of top side buildup layers is equal to the number of backside buildup layers. That is, the package substrate 100 is symmetric. As such, when extra layers are needed on the front-side of the core 105, extra layers may also be formed on the backside of the core 105. For example five layers are provided on the front-side and the backside of the core 105 in FIG. 1B. This leads to a total of ten buildup layers. This increases the Z-height of the package substrate 100, and also results in an increase in the cost of the package substrate 100.

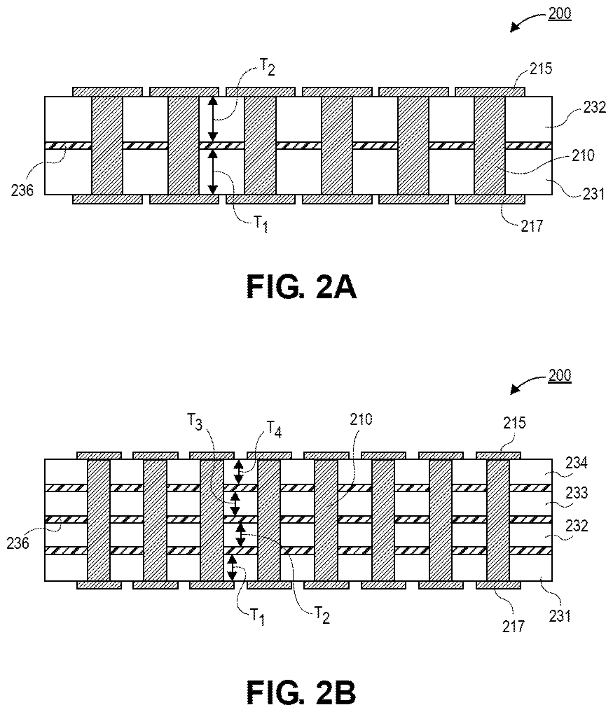

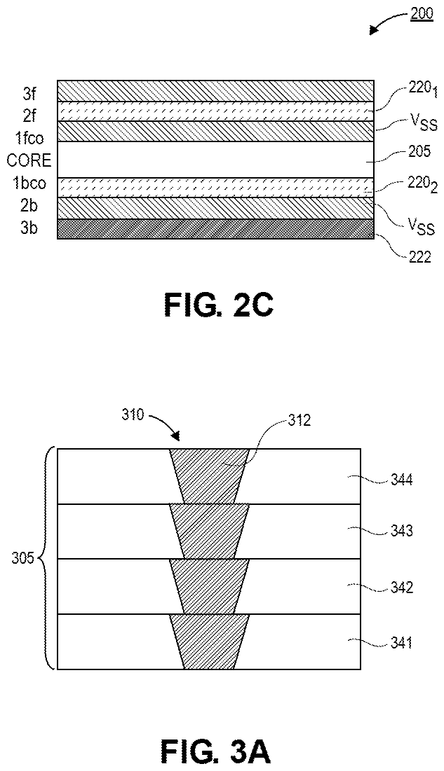

Referring now to FIG. 2A, a cross-sectional illustration of a package substrate 200 is shown, in accordance with an embodiment. In the illustrated embodiment, the core is shown without overlying or underlying buildup layers. As shown, the core may comprise a pair of sub-cores 231 and 232. The sub-cores 231 and 232 may have thicknesses T₁ and T₂ respectively. In an embodiment, the thickness T₁ may be substantially similar to the thickness T₂. However, the thickness T₁ may be different than the thickness T₂ in other embodiments. In a particular embodiment, the thickness T₁ and the thickness T₂ may combine for a total thickness of approximately 200 μm or greater or approximately 250 μm or greater. As used herein, “approximately” may refer to a range of values that are within 10% of the stated value. For example “approximately 200 μm” may refer to a range between 180 μm and 220 μm. In an embodiment, the sub-cores 231 and 232 may be adhered to each other with an adhesive 236.

Since the thicknesses of the sub-cores 231 and 232 are reduced, it is possible to form vias 210 with smaller diameters than the vias 110 described above that are formed with existing processes. For example, the diameter of the vias 210 may be less than approximately 90 μm. Additionally, the pads 215 and 217 may also be reduced in diameter. For example, the pads 215 and 217 may have a diameter that is less than approximately 190 μm.

Referring now to FIG. 2B, a cross-sectional illustration of an electronic package 200 is shown, in accordance with an additional embodiment. In the illustrated embodiment, the core is shown without overlying or underlying buildup layers. As shown, the core may comprise a plurality of sub-cores 231-234. The sub-cores 231-234 may be coupled to each other by adhesive layers 236. In an embodiment, the sub-cores 231-234 may have corresponding thicknesses T₁-T₄. The thicknesses T₁-T₄ may be substantially equal to each other in some embodiments. In other embodiments, the thicknesses T₁-T₄ may be non-uniform. In a particular embodiment, the thicknesses T₁-T₄ may each be approximately 50 μm, in order to provide a total core thickness of the approximately 200 μm.

Since the thicknesses T₁-T₄ are reduced compared to the embodiment shown in FIG. 2A, the vias 210 and the pads 215 and 217 may have relatively smaller dimensions. For example, a diameter of the vias 210 may be approximately 75 μm or smaller. Additionally, the pads 215 and 217 may be approximately 150 μm or smaller. In a particular embodiment, the pitch of the pads 215 and 217 may be substantially equal to a pitch of the bumps of an overlying die (not shown). As such, it is possible to route signaling traces onto the backside of the package substrate 200.

In FIG. 2A, a core with two sub-core layers is shown, and in FIG. 2B, a core with four sub-core layers is shown. However, it is to be appreciated that the core may include any number of sub-core layers. That is, embodiments may include two or more sub-core layers. Increasing the number of sub-cores reduces the thickness of the individual sub-cores, and allows for smaller diameter vias.

An example schematic of the routing layers of the package substrate 200 is shown in FIG. 2C. As shown, the package substrate 200 comprises a core 205 and front-side layers 1fco-3f and backside layers 1bco-3b. In an embodiment, the core 205 may comprise sub-core layers (not shown) similar to the embodiments shown in FIGS. 2A and 2B. As shown, a first signal routing layer 2201 may be provide on the front-side layer 2f, and ground Vss layers may be provided in 1fco and 3f. Similarly, a second signal routing layer 2202 may be provided on the backside layer 2b. A ground Vss may be provided on layer b2, and balls 222 may be provided on layer 3b. The ability to provide signal routing on the backside layers allows for the total number of buildup layers to be reduced compared to the embodiment show in FIG. 1B. Particularly, what originally required ten layers now only needs six layers. As such, the Z-height and cost of the package substrate 200 may be reduced.

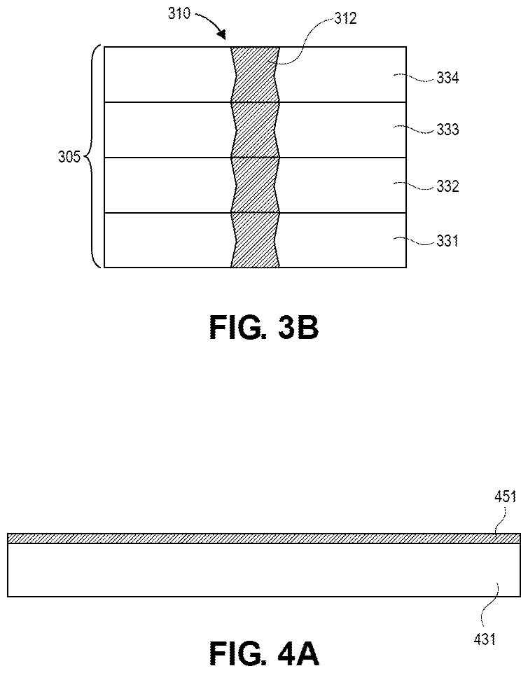

It is to be appreciated that the use of sub-core layers is distinct from other solutions that have been proposed previously. One such solution includes the use of micro-vias in a coreless architecture. Such an architecture is shown in FIG. 3A. As shown, a plurality of buildup layers 341-344 may include a via 310 with portions 312 in each layer. The portions 312 may each have a trapezoidal shape. That is, the top surface of the portions 312 may be wider than the bottom surface of the portions 312. This is due to a single sided laser drilling process. A single sided process is necessary since each layer 341-344 is laminated over the underlying layer 341-344, and there is no access to the backside. As such, the laser drilling can only be made from the top surface. In addition to such a via 310 architecture, it is to be appreciated that the layers 341-344 typically include a material that is different than the material used for cores. That is, the layers 341-344 may be standard buildup layers that do not include reinforcement such as glass fibers or the like.

In contrast, FIG. 3B more accurately depicts the structure of the via 310 through the sub-core layers 331-334 of the core 305. As shown, each sub-core layer 331-334 includes a portion 312 with an hourglass shaped cross-sections. As used herein, an hourglass shaped cross-section may refer to a shape that has a top surface and a bottom surface that is wider than a middle portion of the shape. In an embodiment, the middle portion of the shape may be the narrowest section of the portion 312. In some embodiments, the hourglass shaped cross-section may be symmetrical. For example, the narrowest section of the portion 312 may be approximately at a midpoint through the thickness of the sub-core layer 331-334, and the top surface width and the bottom surface width may be substantially uniform. However, in other embodiments, the narrowest section of the portion 312 may not be at the midpoint of the thickness of the sub-core layer 331-334. Such embodiments may sometimes be referred to as having an asymmetrical shape.

The formation of the hourglass shaped portions 312 is the result of the processing operations used to form the core 305. Particularly, each sub-core layer 331-334 may be fabricated with a dual sided laser drilling process. That is, the laser drilling may be performed on both the top surface of the sub-core layer 331-334 and the bottom surface of the sub-core layer 331-334. Additionally, while the via 310 is shown through a set of four sub-core layers 331-334 in FIG. 3B, it is to be appreciated that vias through any number of sub-core layers may include such a repeating hourglass shape with the number of hourglasses equal to the number of sub-core layers.

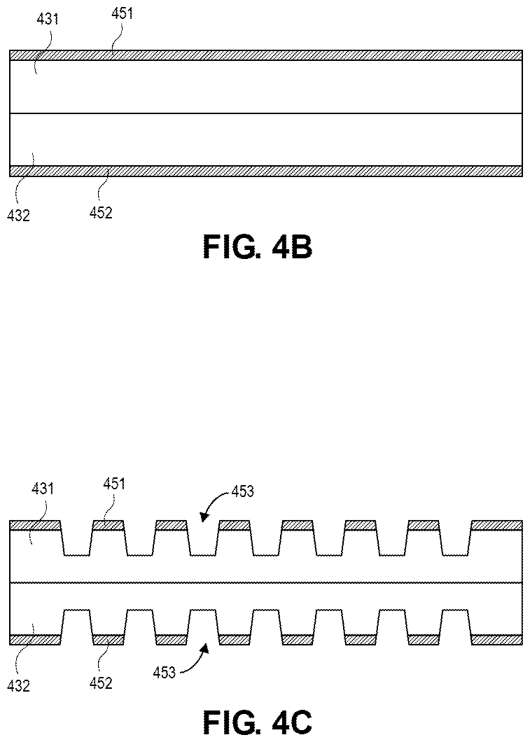

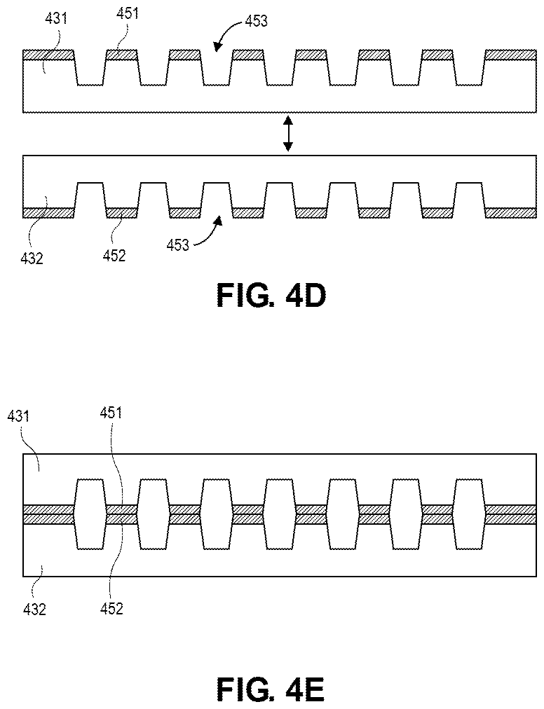

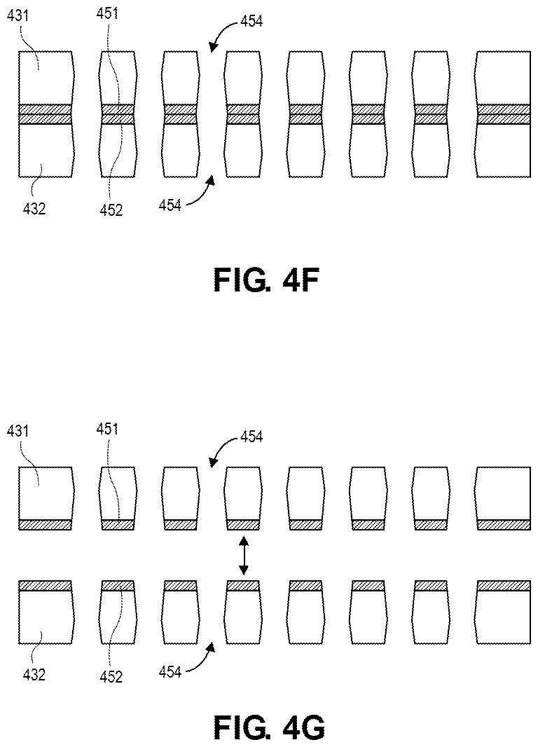

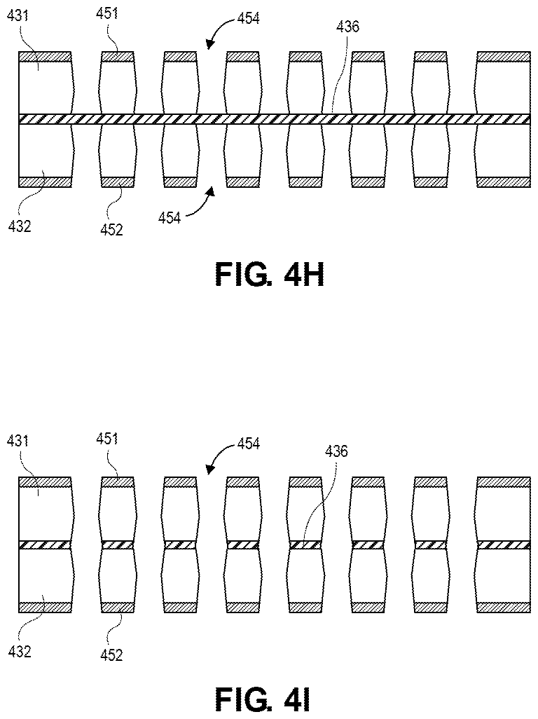

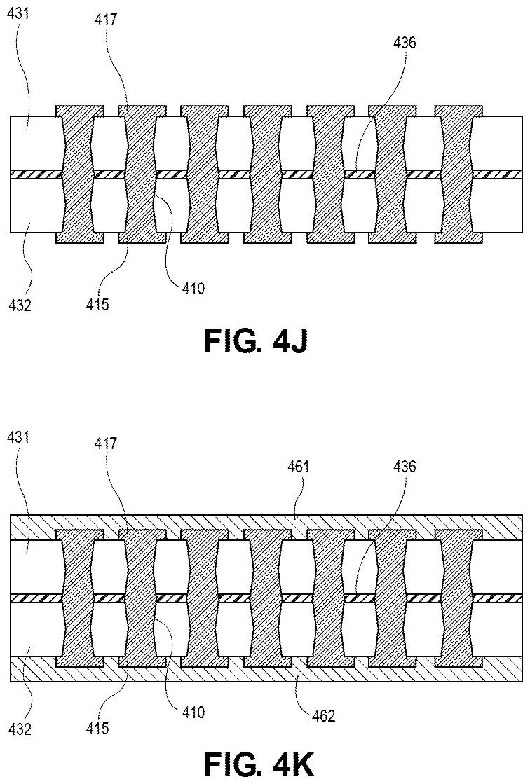

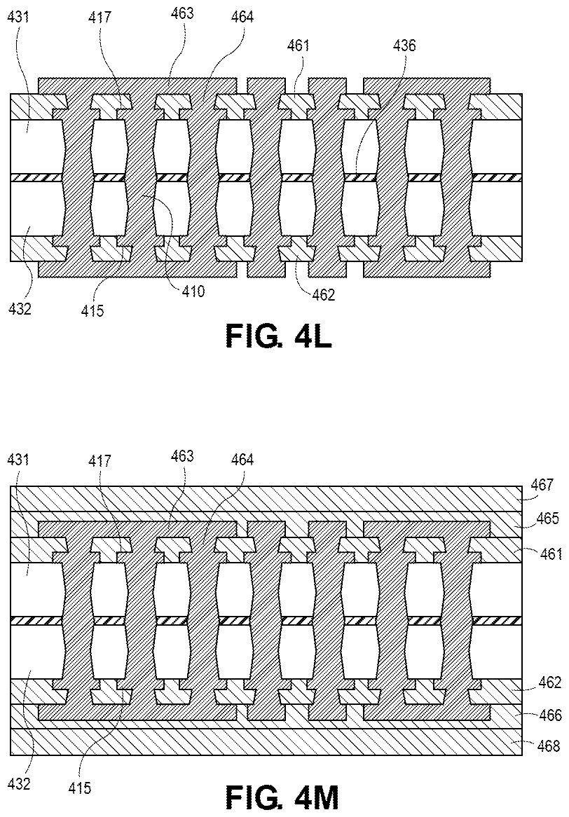

Referring now to FIGS. 4A-4M, a series of cross-sectional illustrations depicting the fabrication of sub-core layers and their assembly into a full core and a package substrate is shown, in accordance with an embodiment. In the illustrated embodiment, the core is shown with two sub-core layers. However, it is to be appreciated that similar processes may be used in order to make a core with any number of sub-core layers.

Referring now to FIG. 4A, a cross-sectional illustration of a first sub-core layer 431 is shown, in accordance with an embodiment. In an embodiment, the first sub-core layer 431 may include a thickness that is less than approximately 200 μm. For example, the first sub-core layer 431 may have a thickness that is approximately 100 μm or smaller, or approximately 50 μm or smaller. In an embodiment, the first sub-core layer 431 may comprise a reinforcement, such as a glass fiber reinforcement. The first sub-core layer 431 may also include a metallic cladding layer 451. For example, the cladding layer 451 may include copper in some embodiments.

Referring now to FIG. 4B, a cross-sectional illustration of the first sub-core layer 431 adhered to a second sub-core layer 432 is shown, in accordance with an embodiment. In an embodiment, the second sub-core layer 432 may be substantially similar to the first sub-core layer 431. That is, a thickness and material composition of the second sub-core layer 432 may be substantially similar to the thickness and material composition of the first sub-core layer 431. In an embodiment, a cladding 452 (e.g., a copper layer) may also be provided on the second sub-core layer 432. The cladding 452 may be oriented away from the cladding 451 of the first sub-core layer 431. That is, the first sub-core layer 431 and the second sub-core layer 432 may be oriented in a back-to-back configuration. In an embodiment, the first sub-core layer 431 and the second sub-core layer 432 may be adhered to each other with a temporary adhesive (not shown). In other embodiments the first sub-core layer 431 and the second sub-core layer 432 may be attached to each other with any suitable means.

Referring now to FIG. 4C, a cross-sectional illustration of the structure after first openings 453 are formed into the first sub-core layer 431 and the second sub-core layer 432 is shown, in accordance with an embodiment. The openings 453 may be formed with a laser drilling process. As such, a dimension of the top of the openings 453 may be larger than a dimension of the bottom of the openings. The openings 453 in the first sub-core layer 431 may be aligned with the openings 453 in the second sub-core layer 432. In an embodiment, the openings 453 may only pass through a partial thickness of the first sub-core layer 431 and the second sub-core layer 432. In a particular embodiment, the depth of the openings 453 may be approximately equal to half the thickness of the sub-core layers 431 and 432.

Referring now to FIG. 4D, a cross-sectional illustration of the structure after the first sub-core layer 431 is released from the second sub-core layer 432 is shown, in accordance with an embodiment. As indicated by the double sided arrow, the first sub-core layer 431 is displaced vertically relative to the second sub-core layer 432. In an embodiment, the separation of the sub-core layers 431 and 432 may be made after an adhesive is deactivated or any other coupling mechanism is released.

Referring now to FIG. 4E, a cross-sectional illustration of the structure after the first sub-core layer 431 and the second sub-core layer 432 are reattached to each other is shown, in accordance with an embodiment. In an embodiment, the first sub-core layer 431 and the second sub-core layer 432 may be flipped over. As such, the cladding layers 451 and 452 may be contacting each other. In an embodiment, the sub-cores 431 and 432 are aligned with each other so that the first openings 453 on each sub-core layer 431 and 432 are provided in a vertical stack. In an embodiment, the first sub-core layer 431 and the second sub-core layer 432 may be adhered to each other with a temporary adhesive (not shown). In other embodiments the first sub-core layer 431 and the second sub-core layer 432 may be attached to each other with any suitable means.

Referring now to FIG. 4F, a cross-sectional illustration of the structure after second openings 454 are formed into the first sub-core layer 431 and the second sub-core layer 432 is shown, in accordance with an embodiment. In an embodiment, the second openings 454 may be formed with a laser drilling process. As such, the second openings 454 may also have a trapezoidal shape. The second openings 454 may extend to the depth of the first openings 453 in order to provide a continuous opening that passes through both the first sub-core layer 431 and the second sub-core layer 432. Due to the double sided laser drilling process, the openings through the first sub-core layer 431 and the second sub-core layer 432 may be referred to as having an hourglass shaped cross-section, similar to embodiments described in greater detail above.

Referring now to FIG. 4G, a cross-sectional illustration of the structure after the first sub-core layer 431 is released from the second sub-core layer 432 is shown, in accordance with an embodiment. As indicated by the double sided arrow, the first sub-core layer 431 is displaced vertically relative to the second sub-core layer 432. In an embodiment, the separation of the sub-core layers 431 and 432 may be made after an adhesive is deactivated or any other coupling mechanism is released.

Referring now to FIG. 4H, a cross-sectional illustration of the structure after the first sub-core layer 431 and the second sub-core layer 432 are reattached is shown, in accordance with an embodiment. In an embodiment, the first sub-core layer 431 and the second sub-core layer 432 may be flipped again so that the claddings 451 and 452 face away from each other. That is, the first sub-core layer 431 and the second sub-core layer 432 may be oriented in a back-to-back configuration. The openings in the first sub-core layer 431 may be aligned with the openings in the second sub-core layer 432 in order to provide a common opening that passes through both the first sub-core layer 431 and the second sub-core layer 432. In an embodiment, the first sub-core layer 431 may be adhered to the second sub-core layer 432 by an adhesive 436. The adhesive 436 may be a permanent adhesive that will be present in the final structure of the electronic package. As shown, the adhesive 436 may disrupt the path of the common openings through the first sub-core layer 431 and the second sub-core layer 432.

Referring now to FIG. 4I, a cross-sectional illustration of the structure after the adhesive 436 is patterned in order to open up the common openings through the first sub-core layer 431 and the second sub-core layer 432 is shown, in accordance with an embodiment. In an embodiment, the adhesive 436 may be patterned with an etching process (e.g., a wet etching process or a dry etching process). The etching process may selectively remove the portions of the adhesive 436 that are present in the common openings. At this point the final structure of the via opening is present. As shown, the via opening may have a cross-section with repeating stacked hourglass shaped regions with a vertical sidewall section between the first sub-core layer 431 and the second sub-core layer 432 (at the location of the adhesive 436).

Referring now to FIG. 4J, a cross-sectional illustration of the structure after the vias 410 are plated and the pads 417 and 415 are patterned is shown, in accordance with an embodiment. In an embodiment, the vias 410 and pads 415 and 417 may be plated with any suitable plating process. In a particular embodiment, the conductive features may be plated with an electroless plating process. In contrast to a plated through hole (PTH) structure that is sometimes used in cores, the entire volume of the openings may be filled with the plating material (e.g., copper). The cladding 451 and 452 may be removed during the patterning process used to form the pads 415 and 417. As such, surfaces of the first sub-core layer 431 and the second sub-core layer 432 may be exposed.

Referring now to FIG. 4K, a cross-sectional illustration of the structure after first buildup layers 461 and 462 are provided over the sub-core layers 431 and 432 is shown, in accordance with an embodiment. In an embodiment, the first buildup layers 461 and 462 may be formed with a lamination process, or any other suitable process common in the art of semiconductor packaging. In an embodiment, the first buildup layers 461 and 462 may cover the surfaces of the pads 415 and 417.

Referring now to FIG. 4L, a cross-sectional illustration of the structure after routing layers 463 are formed over the first buildup layers 461 and 462 is shown, in accordance with an embodiment. In an embodiment, the routing layers 463 may be electrically coupled to pads 415 or 417 through vias 464 that are formed through the first buildup layers 461 and 462. The vias 464 may be laser drilled micro-vias. The vias 464 may have a trapezoidal shape. That is, the vias 464 through the first buildup layers 461 may have a different cross-section than the via 410 through the sub-cores 431 and 432.

Referring now to FIG. 4M, a cross-sectional illustration of the structure after additional buildup layers 465-468 are formed over the sub-core layers 431 and 432. The additional buildup layers 465-468 are shown without conductive routing for simplicity. It is to be appreciated that one or more traces, vias, etc. may be fabricated on and/or in the buildup layers 465-468. In a particular embodiment, a first signal trace is provided in the front-side buildup layers 461, 465, and 467, and a second signal trace is provided in the backside buildup layers 462, 466, and 468. As such, the total layer count of the electronic package may be reduced compared to architectures that do not allow for signal traces to be provided in the backside buildup layers.

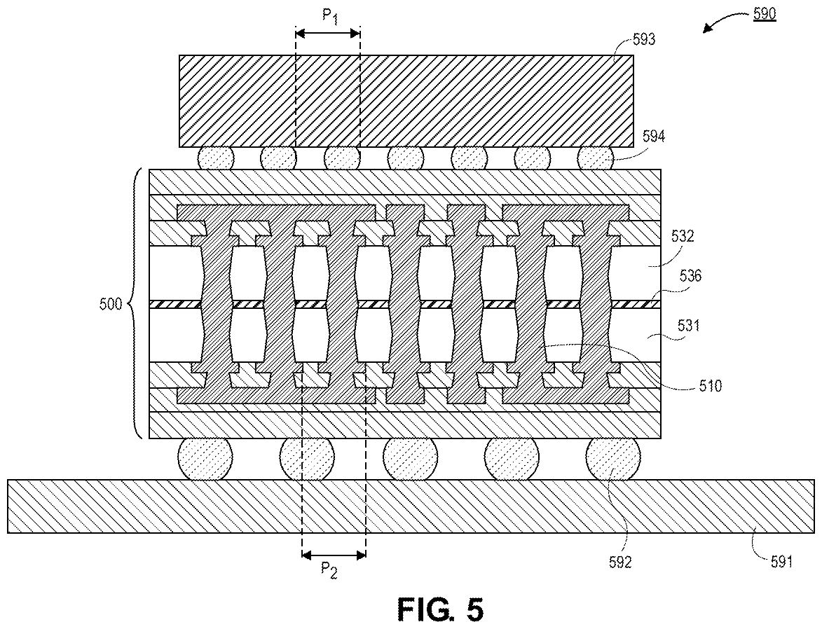

Referring now to FIG. 5, a cross-sectional illustration of an electronic system 590 is shown, in accordance with an embodiment. In an embodiment, the electronic system 590 may comprise a board 591, such as a printed circuit board (PCB). In an embodiment, the package substrate 500 is coupled to the board 591 by interconnects 592. The interconnects 592 are shown as solder balls, but it is to be appreciated that any suitable interconnect architecture may be used. In an embodiment a die 593 may be coupled to the package substrate 500 by interconnects 594. Interconnects 594 are shown as solder bumps, but it is to be appreciated that any first level interconnect (FLI) architecture may be used, in accordance with various embodiments.

In an embodiment, the package substrate 500 may be similar to any of the package substrates described in greater detail herein. Particularly, the package substrate 500 may include a core that comprises two or more sub-core layers 531 and 532. The sub-core layers 531 and 532 may be adhered to each other by an adhesive 536. In an embodiment, vias 510 may pass through the core. In an embodiment, the vias 510 may have a repeating hourglass shaped cross-section that results from the use of a double sided laser drilling process, such as those described in greater detail above.

In an embodiment, the pitch of the pads over the vias 510 may substantially match the pitch of the interconnects 594. For example, interconnects 594 may have a first pitch P₁, and the pads may have a second pitch P₂ that is substantially equal to P₁. As such, it is possible to pass signals through the sub-core layers 531 and 532 in order to route signals on the backside of the package substrate 500. Accordingly, the layer count of the package substrate 500 can be reduced compared to existing solutions.

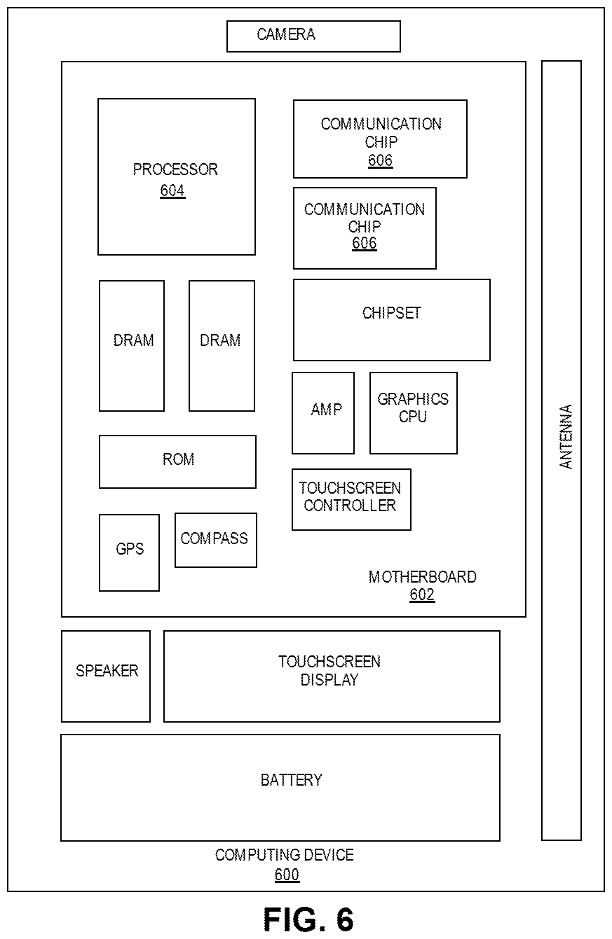

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die of the processor may be part of an electronic system that comprises a package substrate that includes a plurality of sub-core layers with vias that have stacked hourglass shaped cross-sections, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip may be part of an electronic system that comprises a package substrate that includes a plurality of sub-core layers with vias that have stacked hourglass shaped cross-sections, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package substrate, comprising: a core, comprising: a first sub-core layer; a second sub-core layer; a via through the first sub-core layer and the second sub-core layer, wherein the via comprises a first hourglass shape in the first sub-core layer and a second hourglass shape in the second sub-core layer; a front-side buildup layer over the core; and a backside buildup layer under the core.

Example 2: the package substrate of Example 1, further comprising: an adhesive between the first sub-core layer and the second sub-core layer.

Example 3: the package substrate of Example 1 or Example 2, wherein the first sub-core layer and the second sub-core layer comprise a fiber reinforced material.

Example 4: the package substrate of Examples 1-3, wherein a thickness of the first sub-core layer and a thickness of the second sub-core layer are substantially similar.

Example 5: the package substrate of Example 4, wherein the thicknesses of the first sub-core layer and the second sub-core layer are approximately 100 μm or less.

Example 6: the package substrate of Examples 1-3, wherein a thickness of the first sub-core layer is different than a thickness of the second sub-core layer.

Example 7: the package substrate of Examples 1-6, wherein the core further comprises: a third sub-core layer; a fourth sub-core layer, wherein the via passes through the third sub-core layer and the fourth sub-core layer.

Example 8: the package substrate of Examples 1-7, wherein a first signal trace is in the front-side buildup layer, and wherein a second signal trace is in the backside buildup layer.

Example 9: the package substrate of Example 8, wherein a signal for the second signal trace passes through the core.

Example 10: the package substrate of Examples 1-9, wherein a maximum diameter of the via is approximately 100 μm or less.

Example 11: the package substrate of Example 10, wherein the maximum diameter of the via is approximately 75 μm or less.

Example 12: a method of forming a package substrate, comprising: forming a first via opening through a first sub-core layer; forming a second via opening through a second sub-core layer; adhering the first sub-core layer to the second sub-core layer so that the first via opening is aligned over the second via opening; and plating a via through the first via opening and the second via opening.

Example 13: the method of Example 12, wherein forming the first via opening and the second via opening comprises a two sided laser drilling process.

Example 14: the method of Example 13, wherein the first via opening and the second via opening have hourglass shaped cross-sections.

Example 15: the method of Examples 12-14, wherein adhering the first sub-core layer to the second sub-core layer is done with an adhesive.

Example 16: the method of Example 15, wherein the adhesive is patterned with a chemical etching process to couple the first via opening to the second via opening.

Example 17: the method of Examples 12-16, wherein the a thickness of the first sub-core layer and a thickness of the second sub-core layer is approximately 100 μm or less.

Example 18: the method of Example 17, wherein the thickness of the first sub-core layer and the thickness of the second sub-core layer is approximately 50 μm or less.

Example 19: the method of Examples 12-18, wherein a maximum diameter of the via is approximately 100 μm or less.

Example 20: the method of Example 19, wherein the maximum diameter of the via is approximately 75 μm or less.

Example 21: the method of Examples 12-20, further comprising: forming first buildup layers over the first sub-core layer; and forming second buildup layers under the second sub-core layer.

Example 22: the method of Example 21, wherein a first signal trace is in the first buildup layers and a second signal trace is in the second buildup layers.

Example 23: an electronic system, comprising: a board; a package substrate coupled to the board, wherein the package substrate comprises: a first sub-core layer; a second sub-core layer; vias through the first sub-core layer and the second sub-core layer, wherein the vias each comprise repeating hourglass shaped cross-sections; and a die coupled to the package substrate.

Example 24: the electronic system of Example 23, wherein the die has bumps with a first pitch and wherein the vias have the first pitch.

Example 25: the electronic system of Example 23 or Example 24, further comprising: an adhesive between the first sub-core layer and the second sub-core layer.

What is claimed is:

1. A package substrate, comprising:
a core, comprising:
a first sub-core layer;
a second sub-core layer;
a via through the first sub-core layer and the second sub-core layer, wherein the via comprises a first hourglass shape in the first sub-core layer and a second hourglass shape in the second sub-core layer;
a front-side buildup layer over the core; and
a backside buildup layer under the core.

2. The package substrate of claim 1, further comprising:
an adhesive between the first sub-core layer and the second sub-core layer.

3. The package substrate of claim 1, wherein the first sub-core layer and the second sub-core layer comprise a fiber reinforced material.

4. The package substrate of claim 1, wherein a thickness of the first sub-core layer and a thickness of the second sub-core layer are substantially similar.

5. The package substrate of claim 4, wherein the thicknesses of the first sub-core layer and the second sub-core layer are approximately 100 μm or less.

6. The package substrate of claim 1, wherein a thickness of the first sub-core layer is different than a thickness of the second sub-core layer.

7. The package substrate of claim 1, wherein the core further comprises:
a third sub-core layer;
a fourth sub-core layer, wherein the via passes through the third sub-core layer and the fourth sub-core layer.

8. The package substrate of claim 1, wherein a first signal trace is in the front-side buildup layer, and wherein a second signal trace is in the backside buildup layer.

9. The package substrate of claim 8, wherein a signal for the second signal trace passes through the core.

10. The package substrate of claim 1, wherein a maximum diameter of the via is approximately 100 μm or less.

11. The package substrate of claim 10, wherein the maximum diameter of the via is approximately 75 μm or less.

12. A method of forming a package substrate, comprising:
forming a first via opening through a first sub-core layer;
forming a second via opening through a second sub-core layer;
adhering the first sub-core layer to the second sub-core layer so that the first via opening is aligned over the second via opening; and
plating a via through the first via opening and the second via opening.

13. The method of claim 12, wherein forming the first via opening and the second via opening comprises a two sided laser drilling process.

14. The method of claim 13, wherein the first via opening and the second via opening have hourglass shaped cross-sections.

15. The method of claim 12, wherein adhering the first sub-core layer to the second sub-core layer is done with an adhesive.

16. The method of claim 15, wherein the adhesive is patterned with a chemical etching process to couple the first via opening to the second via opening.

17. The method of claim 12, wherein the a thickness of the first sub-core layer and a thickness of the second sub-core layer is approximately 100 μm or less.

18. The method of claim 17, wherein the thickness of the first sub-core layer and the thickness of the second sub-core layer is approximately 50 μm or less.

19. The method of claim 12, wherein a maximum diameter of the via is approximately 100 μm or less.

20. The method of claim 19, wherein the maximum diameter of the via is approximately 75 μm or less.

21. The method of claim 12, further comprising:
forming first buildup layers over the first sub-core layer; and
forming second buildup layers under the second sub-core layer.

22. The method of claim 21, wherein a first signal trace is in the first buildup layers and a second signal trace is in the second buildup layers.

23. An electronic system, comprising:
a board;
a package substrate coupled to the board, wherein the package substrate comprises:
a first sub-core layer;
a second sub-core layer;
vias through the first sub-core layer and the second sub-core layer, wherein the vias each comprise repeating hourglass shaped cross-sections; and
a die coupled to the package substrate.

24. The electronic system of claim 23, wherein the die has bumps with a first pitch and wherein the vias have the first pitch.

25. The electronic system of claim 23, further comprising:
an adhesive between the first sub-core layer and the second sub-core layer.
